(19) United States
(12) Patent Application Publication
(10) Pub. No.: US 2026/0105027 A1
(43) Pub. Date: Apr. 16, 2026

(54) SYSTEM AND METHOD FOR MODEL BASED DATA COMPRESSION

(71) Applicant: Verizon Patent and Licensing Inc., Basking Ridge, NJ (US)

(72) Inventors: Randolph Torres, Merritt Island, FL (US); Charles A Beltran, Netcong, NJ (US); Antra Malhotra, Tampa, FL (US); Matt Sanderson, McKinney, TX (US)

(21) Appl. No.: 18/911,310

(22) Filed: Oct. 10, 2024

(51) Int. Cl. G06F 16/174; G06F 16/901

(52) U.S. Cl. CPC G06F 16/1744; G06F 16/901

(57) ABSTRACT

One or more computing devices, systems, and/or methods for model based data compression are provided. Input data values are converted into grouping structures. Categories are derived and assigned to the grouping structures based upon types of input data values grouped in the grouping structures. Categorical values and time series values are removed from the grouping structures. A model is trained to compress the input data values by representing groupings of the input data values using hash values generated from the grouping structures.

### BACKGROUND

Many computing environments provide storage functionality such as deduplication, compression, encryption, data replication, backup and restore functionality, etc. The storage functionality may be implemented for an on-premise computing environment, a cloud computing environment, or locally on a device. Storage efficiency is improved by implementing compression to reduce the amount of storage consumed by data. Lossy compression reduces a file size by removing some of the original data. Lossless compression reduces a file size by removing metadata.

### BRIEF DESCRIPTION OF THE DRAWINGS

While the techniques presented herein may be embodied in alternative forms, the particular embodiments illustrated in the drawings are only a few examples that are supplemental of the description provided herein. These embodiments are not to be interpreted in a limiting manner, such as limiting the claims appended hereto.

FIG. 1 illustrates an example of a system for model based data compression where a model is trained to compress data, in accordance with an embodiment of the present technology;

FIG. 2 illustrates an example of a system for model based data compression where a trained model comprises data, in accordance with an embodiment of the present technology;

FIG. 3 illustrates an example of a system for model based data compression where a feedback loop is implemented to train a deployed model, in accordance with an embodiment of the present technology;

FIG. 4 is a flow chart illustrating an example method for model based data compression, in accordance with an embodiment of the present technology;

FIG. 5A illustrates an example of a system for model based data compression where input data values are compressed, in accordance with an embodiment of the present technology;

FIG. 5B illustrates an example of a system for model based data compression where data values are reconstructed from compressed data, in accordance with an embodiment of the present technology;

FIG. 6 is an illustration of example networks that may utilize and/or implement at least a portion of the techniques presented herein;

FIG. 7 is an illustration of a scenario involving an example configuration of a computer that may utilize and/or implement at least a portion of the techniques presented herein;

FIG. 8 is an illustration of a scenario involving an example configuration of a client that may utilize and/or implement at least a portion of the techniques presented herein;

FIG. 9 is an illustration of a scenario featuring an example non-transitory machine readable medium in accordance with one or more of the provisions set forth herein.

### DETAILED DESCRIPTION OF EXAMPLE EMBODIMENTS

Subject matter will now be described more fully hereinafter with reference to the accompanying drawings, which form a part hereof, and which show, by way of illustration, specific example embodiments. This description is not intended as an extensive or detailed discussion of known concepts. Details that are well known may have been omitted, or may be handled in summary fashion.

The following subject matter may be embodied in a variety of different forms, such as methods, devices, components, and/or systems. Accordingly, this subject matter is not intended to be construed as limited to any example embodiments set forth herein. Rather, example embodiments are provided merely to be illustrative. Such embodiments may, for example, take the form of hardware, software, firmware or any combination thereof. The following provides a discussion of some types of computing scenarios in which the disclosed subject matter may be utilized and/or implemented.

Systems and methods are provided for model based data compression. The disclosed model based data compression provides improved compression and reduces storage consumption compared to conventional compression techniques. Conventional compression merely compresses data without taking into account the type of data, what the data representations are, and/or relationships amongst data values. Because conventional compression does not understand what is represented by the data, conventional compression techniques may be capable of merely removing some bytes from character fields, binary fields, or numeric fields, which might provide 20% to 30% compression. The compression savings provided by conventional compression is insufficient when dealing with large amounts of data, such as where performance data of a communication network is being stored (e.g., gigabytes of performance key indicator data may be stored per second for a radio access network).

The disclosed model based data compression improves upon these conventional compression mechanisms by training a model to understand and take into account the type of data, what the data representations are, and/or relationships amongst data values (e.g., time series data values representing a vehicle traveling at 60 mph for an hour with little change or no change in speed data values). The disclosed model based data compression may achieve about 70% to about 80% compression compared to the 20% to 30% compression provided by the conventional compression mechanisms. Such data compression may be achieved by grouping certain key performance indicators or performance metrics into values. For example, download speeds between 1.2M and 1.9M may be rounded to 1.5M so all values between 1.2M and 1.9M can be represented by a single value of 1.5M. The disclosed model based data compression greatly reduces storage resource utilization, power consumption, cooling, and the potential of disk failures because less disks can be used to store the same amount of data. These technical advantages provided by the model based data compression may be significant when large amounts of data is being stored over time such as the performance data of the communication network (e.g., performance data from 4G, 5G, and/or other network equipment).

The model based data compression achieves higher compression for reduced storage by utilizing a model, such as a large language model, for compressing the data based upon categories of the data. A category may be defined as a range of values for a particular type of data value (e.g., a category corresponding to vehicle speeds between 58 and 60). The model may be trained to identify any type of category of data values, such as regions, markets, sectors, carriers, eNodeB, gNodeB, and/or other categories of perform data for the communication network, or speed, gas mileage, battery temperature, and/or other categories of vehicle data, for example.

The model is capable of identifying similar types of categorical data values that can be represented by a single hash value because the model has been trained to take into account the type of data, what the data representations, and/or relationships amongst data values. For example, network equipment may provide communication functionality for a sports stadium. If the sports stadium is empty for a period of time such as on a particular day, then the network equipment may be idle and/or key performance indicators for the network equipment may have little to no fluctuation. Storing these key performance indicators during stable/idle times at full data resolution is similar to storing a 1-hour 8k video of an empty room, which consumes a large amount of storage (e.g., storing the same/similar video frames with little to no pixel movement). Accordingly, the model based data compression can identify such similar data values (e.g., idle signals in the communication network where key performance indicators and other telemetry data has little to no change) for compression by representing the similar data values with a single hash value, thus achieve far greater compression than conventional compression techniques. So instead of storing hours of the same/similar performance data generated by the network equipment within the empty stadium, merely a few hash values are used to represent such similar data values, thus achieving 70% to about 80% compression.

As another example, vehicle telemetry data may be collected from vehicles as data values corresponding to vehicle speed, oil level, battery temperature, imagery from cameras, braking distance information, and/or a variety of other information collected by the vehicles. The data values may be received from the vehicles over a communication network for storage such as within a cloud computing environment. The data values may be received from hundreds of thousands or more vehicles, and thus a large amount of data is being stored every second. Conventional compression that provides maybe 20% to 30% compression is inadequate for storing such a large amount of data values over time. Accordingly, the model based data compression can utilize the model to identify similar data values associated with the same category (e.g., vehicle speeds between 63 mph and 67 mph), such as where a vehicle has been traveling on cruise control for an hour at 65 mph. Thus, an hour's worth of data values will be the same 65 mph data value for the vehicle. The model is capable of detecting this as part of compressing the data values, and thus may represent the data values as a single hash value (e.g., a 4 byte hash value representing vehicle speed data values between 63 mph and 67 mph). The model is capable of reconstructing the data values from the compressed data such as by reconstructing the vehicle speed data values from the hash value.

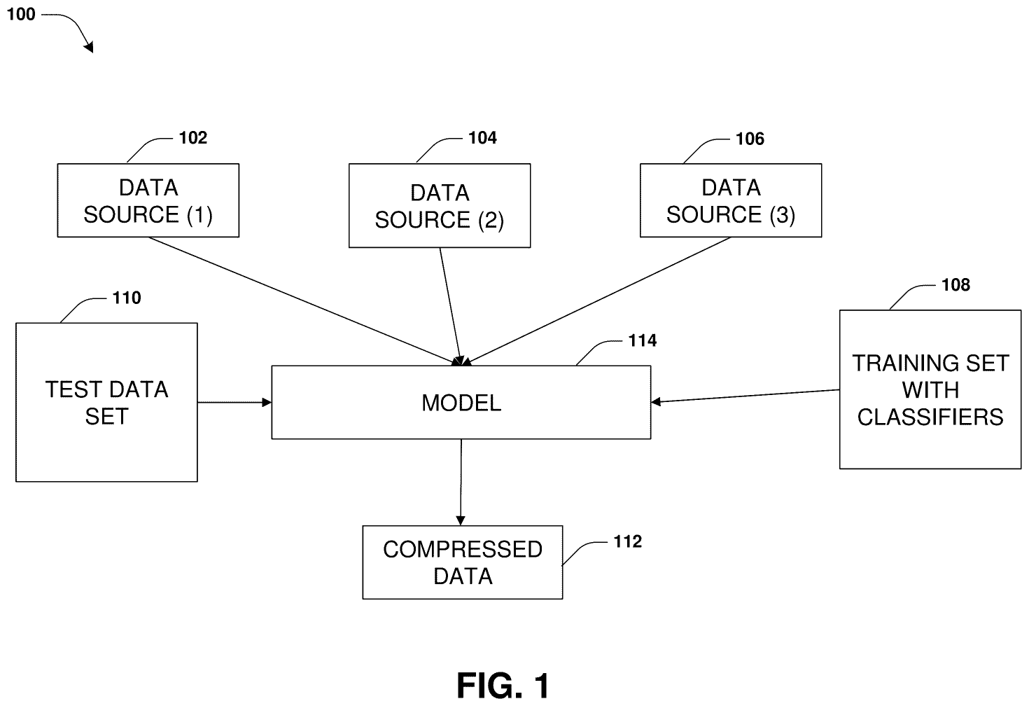

FIG. 1 illustrates an example of a system 100 for model based data compression. A model 114 such as a large language model may be trained to compress data from various data sources to create compressed data 112. The model 114 may be trained to compress data values from a first data source 102, such as radio access network (RAN) data from network equipment of a communication network. The model 114 may be trained to compress data values from a second data source 104, such as performance data (e.g., unified communication services performance data). The model may be trained to compress data from a third data source 106, such as high volume data (e.g., telemetry from vehicles, data from IoT devices, etc.). It may be appreciated that the model 114 may be trained on any type of data.

The model 114 may be trained with a test data set 110. The test data set 110 may include input data values that have additional information (hints) to help train the model 114 to identify sets of the same/similar data values that can be grouped together and represented as a single hash value. For example, the test data set 110 may comprise key performance indicators of network equipment over time that have data values with little to no change (e.g., key performance indicates of idle network equipment with values within a particular range of values), and thus could be grouped and represented by a single hash value. The model may be trained with a training set 108 of data values with classifiers. The training set 108 includes additional information (hints) on classifiers for different types of data. The additional information may indicate/hint that certain fields can be grouped together when identified in a dataset (e.g., group together data values associated with regions, markets, sectors, carriers, eNodeBs, gNodeGs, etc.). In some embodiments, the training set 108 may be user specified such as where a user can input the additional information as plain text into a user interface. In this way, the model 114 is trained using the input data values from the various data sources, the test data set 110, and/or the training set 108 for creating the compressed data 112, such as where multiple input data values are grouped together and represented by a single hash value.

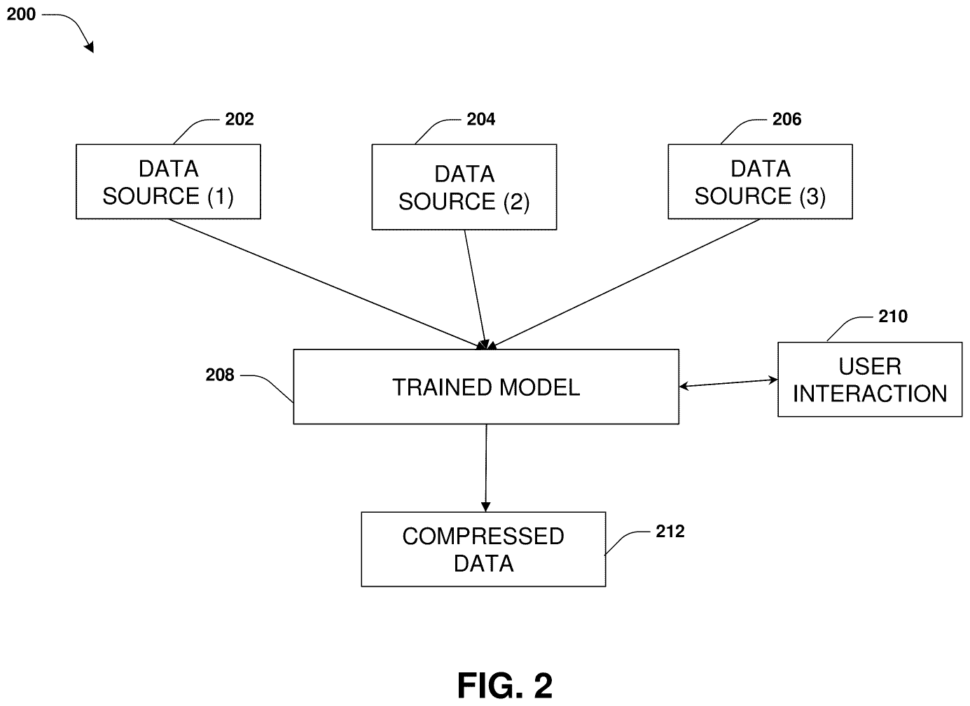

FIG. 2 illustrates an example of a system 200 for model based data compression. A trained model 208, such as a trained large language model, may have been trained to compress data by taking into account the type of data, what the data representations, and/or relationships amongst data values. For example, the trained model 208 may have been trained to identify and compress together a time series of data values representing key performance indicators of network equipment with idle communication activity (e.g., network equipment within an empty stadium). In some embodiments, the trained model 208 may correspond to the model 114 that was trained by system 100.

The trained model 208 may be deployed into a production environment such as on-premises, within a cloud computing environment, on a storage server or virtual machine of a storage environment, etc. The trained model 208 may compress data values from various data sources, such as a first data source 202, a second data source 204, a third data source 206, and/or other data sources to create compressed data 212 where certain groupings of data values are represented by hash values. For example, a 4 byte hash value can be used to represent a 50 byte grouping of data values, thus providing significant storage savings.

User interaction 210 may be supported for the trained model 208. In some embodiments, the trained model 208 can submit questions through a user interface to a user. For example, a question may ask “should these two types of data values be grouped together or treated as separate categories,” “do these data values belong to a carrier category,” “can you define a new category for this data value,” “does column MTK representing marketing data,” and/or a wide variety of other questions related to how to understand data values for grouping and compressing the data values. The user may submit answers through the user interface for updating or further training the trained model 208, such as where a new user defined category is created (e.g., a category where vehicle speed data between 58 mph and 62 mph is to be grouped together for compression that will represent the vehicle speed data within a single hash value). The trained model 208 may ask, through the user interface, the user about missing items (e.g., a missing data value after the compressed data 212 has been decompressed), unknown items (e.g., the trained model 208 may be unable to group a data value based upon currently known categories), inconsistency categories (e.g., a data value may not be consistent with a category used to group the data value), too many timestamps (e.g., time series data values with timestamps may be grouped into grouping structures for compression, and thus a certain number of timestamps may be grouped together), etc. In some embodiments, the user may directly input instructions and/or feedback through the user interface for updating or further training the trained model 208.

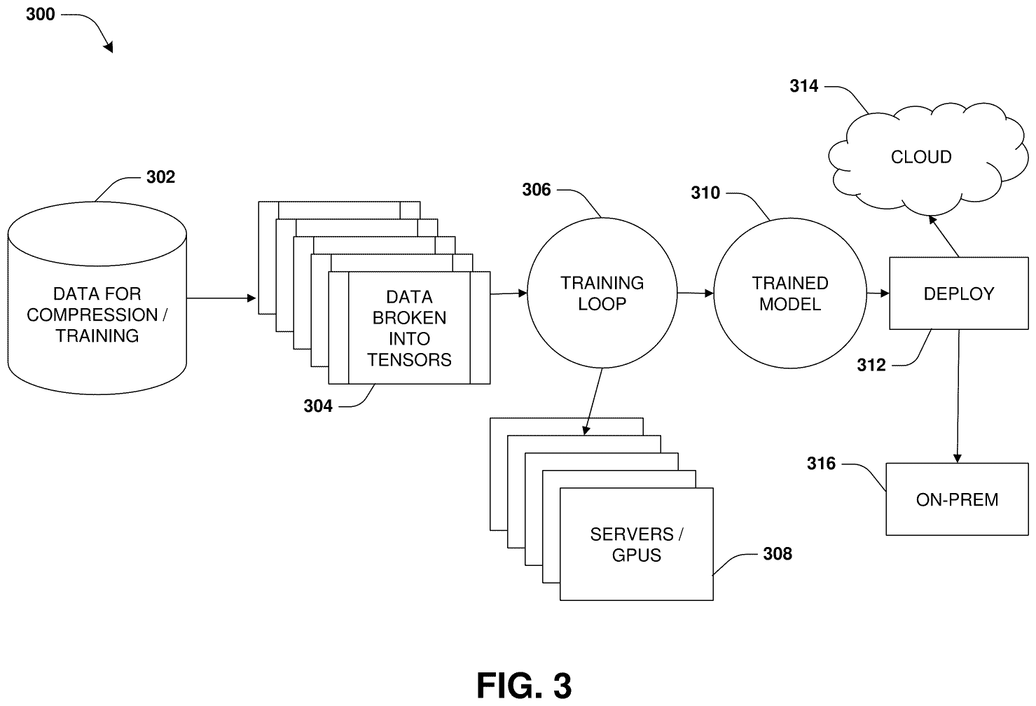

FIG. 3 illustrates an example of a system 300 for model based data compression. A trained model 310 may be deployed 312 to a cloud computing environment 314, an on-premises environment 316 or other computing environment for compressing data. Compute resources 308 such as servers and/or graphics processing units may execute the trained model 310. The trained model 310 may be trained over multiple iterations of a training loop 306 over time such as to learn new categories, adjust logic used to determine what data values to group into a category, adjust compression logic, modify parameters or weights of the trained model 310, etc. In some embodiments, data 302 may be used to train the trained model 310 as part of the training loop 306. In some embodiments, the data 302 may be received for compression while the trained model 310 has been deployed for production.

The data 302 may comprise input data values that are converted to grouping structures, such as where the data values are broken 304 into tensors or other types of structures into which data may be grouped. That is, similar types of data values may be grouped together, and categories may be assigned to the grouping structures (tensors) based upon the type of data values grouped into the grouping structures (e.g., a carrier category for a first grouping structure for carrier based performance data having values within a particular range, an eNodeB category for a second grouping structure for eNodeB performance data having values within a particular range, etc.). Categorical values and/or time series values may be removed from the grouping structures so that the same or similar data values over a time interval are merely represented as a single value. The trained model 310 is trained to compress the input data values by representing groupings of the input data values using hash values generated from the grouping structures. In this way, the categories and hash values are stored as the compressed data to represent the input data values.

In some embodiments of compressing the data 302, the trained model 310 may identify a timespan where data values (e.g., a speed of a vehicle) are the same/similar such as at 12:01, 12:02, 12:03, 12:04, etc. Instead of storing that same value each time, merely one instance of the data value is stored with metadata (metadata of a grouping structure) indicating the time series grouping, which may be stored as a category and hash value. The metadata may indicate that the single data value is for a time series that includes 12:01, 12:02, 12:03, 12:04, etc. In some embodiments, the hash value is a compressed value of a performance indicator, performance data, or other type of data. For example, download speeds between 1.2M and 1.9M may be rounded to 1.5M so all values between 1.2M and 1.9M can be represented by a single value of 1.5M.

When a request is received for the time series data, the time series data is rebuilt on the fly where the hash value and metadata are broken back out into the time series data. A small byte version of the data representation is expanded back into an original size by utilizing the value ranges for those data values. For example, a key performance indicator may be a floating value for 94.5%. The trained model 310 may utilize a category to group together any data values within a range of 85% to 95%, which are treated as the same value such as 90%. Accordingly, the 94.5% value for the key performance indicator is grouped and compressed together with other data values from 85% to 95%, which are represented by a hash value as part of compression. For example, the hash value may be a 4 byte code to represent key performance indicators with values between 85% and 95%. As part of decompression, the hash value (4 byte code) is used to rebuild a value such as 90% for the key performance indicators that were in the range from 85% to 95%. So, the key performance indicators that were grouped into a grouping structure based upon the key performance indicators having values within the range from 85% to 95% and were compressed and represented by a single hash value, will be decompressed with a value of 90% that is accurate enough for most analytics and use cases that process the key performance indicators (e.g., 5% deviation may be acceptable). In this way, a range is created for a category such as 85% to 95% for certain types of data (e.g., a voice quality key performance indicator, a throughput key performance indicator, a download speed key performance indicator, etc.). Data values within that range are designated as part of a category of a grouping structure, and are thus grouped into the grouping structure to be compressed and represented by a single hash value.

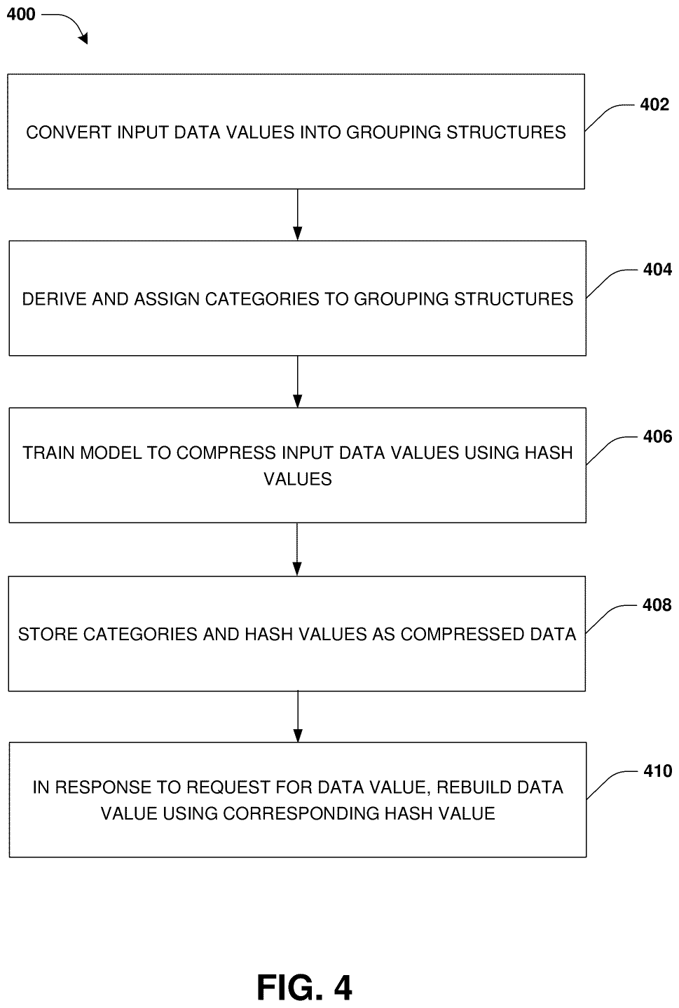

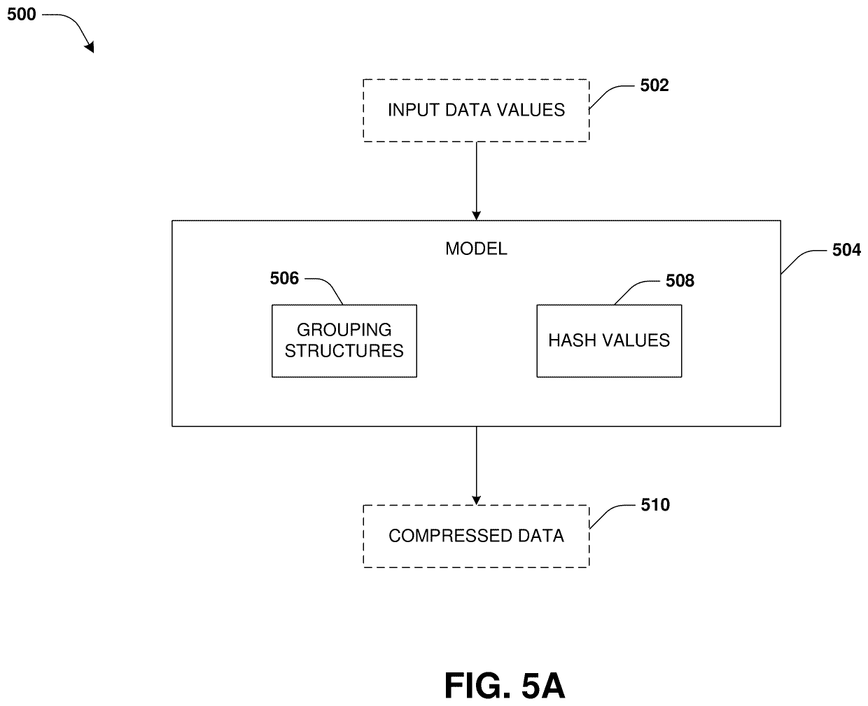

FIG. 4 is a flow chart illustrating an example method 400 for model based data compression, which is illustrated by system 500 of FIGS. 5A and 5B. A model 504, such as a large language model, may be trained to compress input data values 502 (e.g., key performance indicators, performance data, etc.) to create compressed data 510. As part of training the model 504, the input data values 502 are converted into grouping structures 506 (e.g., tensors), during operation 402 of method 400. During operation 404 of method 400, categories are derived and assigned to the grouping structures based upon the type of input data values (e.g., upload speeds, download speeds, throughput, etc.) grouped into the grouping structures 506. For example, a range of values (e.g., values 15 to 19 for an upload speed) may be designated as a category for a grouping structure, and thus upload speed data values with values between 15 and 19 are grouped into the grouping structure. During operation 406 of method 400, categorical values and time series values are removed from the grouping structures as part of compression. For example, a value of 17 may repeatedly occur every second from 2:30 pm to 5:30 pm, and thus merely a single instance of 17 is retained and metadata is used to indicate that the value of 17 is for time series data of values occurring every second from 2:30 pm to 5:30 pm. In this way, upload speed data values with a value between 15 and 19 are grouped into the grouping structure, while data values with other values are grouped into other grouping structures.

During operation 408 of method 400, the model 504 is trained to compress the input data values 502 by representing groupings of the input data values 502 using hash values 508 generated from the grouping structures 506. For example, a single hash value (e.g., a 4 byte value) may be used to represent the input data values with values between 15 and 17 that are grouped into the grouping structure. Metadata may be used to indicate that the input data values, within the grouping structure and represented by the hash value, are part of time series data of values occurring every second from 2:30 pm to 5:30 pm. In some embodiments, the model 504 is trained using a training data set including classifiers for different types of input data values (e.g., classifiers used to identify categories of input data values). In some embodiments, the model 504 is trained using a training data set including user specified classifiers for different types of input data values (e.g., a user may define classifiers of a new category). In some embodiments, the model 504 is trained using a training data set including training data values and hints for how to group the training data values.

In some embodiments, a user is provided with an artificial intelligence (AI) interface (e.g., a chat bot, a text input interface associated with the model 504, etc.). The model 504 may pose questions through the AI interface to the user and/or receive answers from the user through the AI interface. In some embodiments, text-based input may be received through the AI interface. The text-based input may describe a category for data values, summations, groupings, counts, and/or columns to combine as part of the compression provided by the model 504. For example, various devices may be connected to a communication network. Key performance indicators can have different names and values amongst the difference devices (e.g., different device manufacturers may use different labels for the same key performance indicator), such as for download bandwidth, download throughput, received traffic, and/or other names that represent the same metric. The user is capable of modifying and/or specifying that these names/values all represent the same metric such as download throughput. In another example, key performance indicators from difference devices can have higher or lower values due to logic within a device. A user can normalize these values to mean or represent the same metric/value. For example, 50M download on one device may be the equivalent of 45M on another device because the device may take into consideration metadata, timing, and/or other factors that the other devices does not take into account.

In this way, the model 504 may be trained based upon the text-based input.

In some embodiments, the model 504 is trained with patterns corresponding to grouped columns within which the input data values are stored (e.g., patterns of vehicle speed values over time, patterns of braking behavior over time, patterns of fuel consumption over time, etc.). In some embodiments, previously learned data sets and schemas (e.g., a schema defining columns such as a vehicle speed column, a fuel consumption column, a braking behavior column, etc.) are evaluated to identify patterns used to train the model 504. The patterns may correspond to grouped columns within which the input data values 502 are stored.

In some embodiments of compressing the input data values 502 to create the compressed data 510, the input data values are transformed or represented using image data representations (e.g., treated by the model 504 as images such as where images depicting different variations of a white coffee mug may be grouped together). The image data representations are grouped into the grouping structures (e.g., tensors of image data representations having vehicle speed values within a range such as 60 mph to 65 mph, and thus a range may be a category). The image data representations are compressed by storing a single value per category, such as where a single hash value represents a range (category) of vehicle speed values between 60 mph to 65 mph).

In some embodiments of compressing the input data values 502 to create the compressed data 510, a set of input data values associated with a category are identified (e.g., vehicle speeds within an aggregate set of values between 70 and 90; vehicle speeds with a same value of 50; etc.). The set of input data values are grouped into a grouping structure. The input data values within the grouping structure are represented by a hash value.

During operation 410 of method 400, the categories (e.g., metadata used to identify a time range of time series data represented by a hash value) and the hash values 508 are stored as the compressed data 510 representing the input data values 502.

In some embodiments where the model 504 is deployed for compressing data, the model 504 is used to compress data values by predicting hash values to store in place of the data values based upon the categories. Feedback data may be generated based upon the predicted hash values. The feedback data may be used to train the model 504, such as to modify classifiers, logic, parameters, weights, and/or other functionality used by the model 504 to group and compress input values. In some embodiments, the model 504 may generate a new grouping structure based upon a category determined by the model 504. The model 504 may be trained based upon data values grouped into the new grouping structure and a hash value assigned to the new grouping structure. In some embodiments, the model 504 may be updated/trained based upon user input specifying missing data values, unknown data values, inconsistency categories, and/or timestamp issues.

A request 520 may be received for data values 524 that were compressed by the model 504 as the compressed data 510, as illustrated by FIG. 5B. For example, a data analytics service may request time series telemetry data of a vehicle. The model 504 may be used as part of a reconstruction process 522 to rebuild the data values 524 from the compressed data 510, such as by reconstructing the data values 524 from a hash value used to representing the data values, and by using metadata specifying time series data information for the data values such as a time range of the data values 524. In this way, the data values 524 are reconstructed as part of processing the request 520.

According to some embodiments, a method is provided. The method includes converting input data values into grouping structures; deriving and assigning categories to the grouping structures based upon types of input data values grouped into the grouping structures; removing categorical values and time series values from the grouping structures; training a model to compress the input data values by representing groupings of the input data values using hash values generated from the grouping structures; and storing the categories and hash values as compressed data representing the input data values.

According to some embodiments, the method includes compressing, by the model, data values by predicting hash values to store in place of the data values based upon the categories.

According to some embodiments, the method includes generating feedback data based upon the predicted hash values; and training the model using the feedback data.

According to some embodiments, the method includes receiving user input identifying at least one of a missing data value from the compressed data, an unknown data value within the compressed data, an inconsistency category, or a timestamp issue; and training the model based upon the user input.

According to some embodiments, the method includes evaluating the input data values to identify a set of input data values associated with a category; grouping the set of input data values into a grouping structure; and compressing one or more input data values within the grouping structure by representing the one or more input data values with a hash value, wherein the one or more input data values are representative of a same value.

According to some embodiments, the method includes evaluating the input data values to identify a set of input data values associated with a category; grouping the set of input data values into a grouping structure; and compressing one or more input data values within the grouping structure by representing the one or more input data values with a hash value, wherein the one or more input data values are representative of an aggregated set of values.

According to some embodiments, the grouping structure comprises a tensor, wherein the input data values comprise key performance indicator data, and wherein the model is a large language model.

According to some embodiments, the method includes receiving a request for one or more input data values; retrieving a hash value representing the one or more input data values; and reconstructing the one or more input data values from the hash value.

According to some embodiments, a system comprising one or more processors configured for executing the instructions to perform operations, is provided. The operations include converting input data values into grouping structures; deriving and assigning categories to the grouping structures based upon types of input data values grouped into the grouping structures; removing categorical values and time series values from the grouping structures; training a model to compress the input data values by representing groupings of the input data values using hash values generated from the grouping structures; and storing the categories and hash values as compressed data representing the input data values.

According to some embodiments, the operations include training the model using a training data set including classifiers for different types of input data values.

According to some embodiments, the operations include training the model using a training data set including user specified classifiers for different types of data values.

According to some embodiments, the operations include training the model using a training data set including training data values and hints for how to group the training data values.

According to some embodiments, the operations include providing a user with an artificial intelligence interface; receiving text from the user through the artificial intelligence interface, wherein the text describes a grouping for data values; and training the model based upon the text.

According to some embodiments, the operations include providing a user with an artificial intelligence interface; receiving text from the user through the artificial intelligence interface, wherein the text describes at least one of summations, groupings, counts, or columns to combine as part of compression provided by the model; and training the model based upon the text.

According to some embodiments, the operations include generating, by the model, a new grouping structure based upon a category determined by the model; and training the model based upon the data values grouped into the new grouping structure and a hash value assigned to the new grouping structure.

According to some embodiments, the operations include training the model with patterns corresponding to grouped columns within which the input data values are stored.

According to some embodiments, a non-transitory computer-readable medium storing instructions that when executed facilitate performance of operations, is provided. The operations include converting input data values into grouping structures; deriving and assigning categories to the grouping structures based upon types of input data values grouped into the grouping structures; removing categorical values and time series values from the grouping structures; training a model to compress the input data values by representing groupings of the input data values using hash values generated from the grouping structures; and storing the categories and hash values as compressed data representing the input data values.

According to some embodiments, the operations include transforming the input data values into image data representations; grouping the image data representations into the grouping structures; and compressing the image data representations by storing a single value per category.

According to some embodiments, the operations include evaluating previously learned dataset and schemas to identify patterns for compression, wherein the patterns correspond to grouped columns within which the input data values are stored; and training the model with the patterns.

According to some embodiments, the operations include receiving a request for data values associated with a category; and rebuilding the data values from hash values assigned to the category.

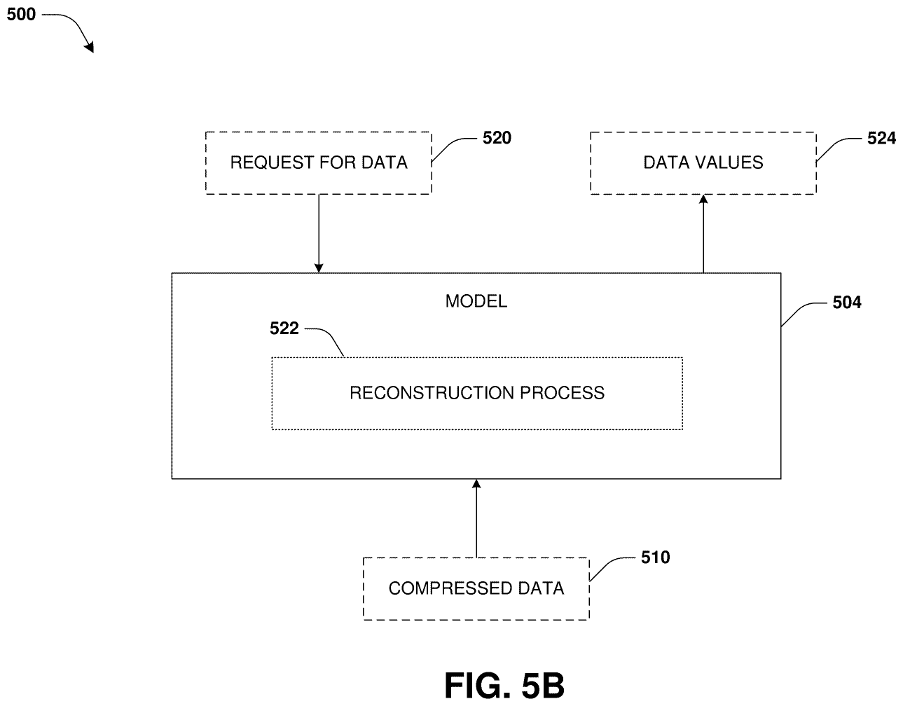

FIG. 6 is an illustration of a scenario 600 involving an example non-transitory machine readable medium 602. The non-transitory machine readable medium 602 may comprise processor-executable instructions 612 that when executed by a processor 616 cause performance (e.g., by the processor 616) of at least some of the provisions herein. The non-transitory machine readable medium 602 may comprise a memory semiconductor (e.g., a semiconductor utilizing static random access memory (SRAM), dynamic random access memory (DRAM), and/or synchronous dynamic random access memory (SDRAM) technologies), a platter of a hard disk drive, a flash memory device, or a magnetic or optical disc (such as a compact disk (CD), a digital versatile disk (DVD), or floppy disk). The example non-transitory machine readable medium 602 stores computer-readable data 604 that, when subjected to reading 606 by a reader 610 of a device 608 (e.g., a read head of a hard disk drive, or a read operation invoked on a solid-state storage device), express the processor-executable instructions 612. In some embodiments, the processor-executable instructions 612, when executed cause performance of operations, such as at least some of the example method 400 of FIG. 4, for example. In some embodiments, the processor-executable instructions 612 are configured to cause implementation of a system, such as at least some of the example system 100 of FIG. 1, at least some of the example system 200 of FIG. 2, at least some of the example system 300 of FIG. 3, and/or at least some of the example system 500 of FIGS. 5A and 5B.

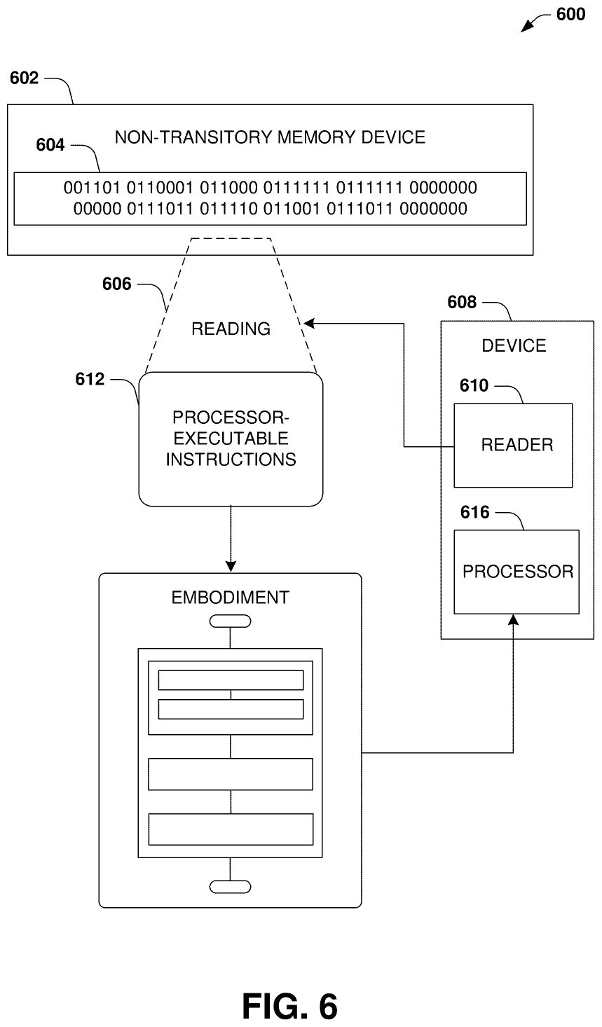

FIG. 7 is an interaction diagram of a scenario 700 illustrating a service 702 provided by a set of computers 704 to a set of client devices 710 via various types of transmission mediums. The computers 704 and/or client devices 710 may be capable of transmitting, receiving, processing, and/or storing many types of signals, such as in memory as physical memory states.

In some embodiments, the computers 704 may be host devices and/or the client device 710 may be devices attempting to communicate with the computer 704 over buses for which device authentication for bus communication is implemented.

The computers 704 of the service 702 may be communicatively coupled together, such as for exchange of communications using a transmission medium 706. The transmission medium 706 may be organized according to one or more network architectures, such as computer/client, peer-to-peer, and/or mesh architectures, and/or a variety of roles, such as administrative computers, authentication computers, security monitor computers, data stores for objects such as files and databases, business logic computers, time synchronization computers, and/or front-end computers providing a user-facing interface for the service 702.

Likewise, the transmission medium 706 may comprise one or more sub-networks, such as may employ different architectures, may be compliant or compatible with differing protocols and/or may interoperate within the transmission medium 706. Additionally, various types of transmission medium 706 may be interconnected (e.g., a router may provide a link between otherwise separate and independent transmission medium 706).

In scenario 700 of FIG. 7, the transmission medium 706 of the service 702 is connected to a transmission medium 708 that allows the service 702 to exchange data with other services 702 and/or client devices 710. The transmission medium 708 may encompass various combinations of devices with varying levels of distribution and exposure, such as a public wide-area network and/or a private network (e.g., a virtual private network (VPN) of a distributed enterprise).

In the scenario 700 of FIG. 7, the service 702 may be accessed via the transmission medium 708 by a user 712 of one or more client devices 710, such as a portable media player (e.g., an electronic text reader, an audio device, or a portable gaming, exercise, or navigation device); a portable communication device (e.g., a camera, a phone, a wearable or a text chatting device); a workstation; and/or a laptop form factor computer. The respective client devices 710 may communicate with the service 702 via various communicative couplings to the transmission medium 708. As a first such example, one or more client devices 710 may comprise a cellular communicator and may communicate with the service 702 by connecting to the transmission medium 708 via a transmission medium 709 provided by a cellular provider. As a second such example, one or more client devices 710 may communicate with the service 702 by connecting to the transmission medium 708 via a transmission medium 709 provided by a location such as the user's home or workplace (e.g., a Wi-Fi (Institute of Electrical and Electronics Engineers (IEEE) Standard 802.11) network or a Bluetooth (IEEE Standard 802.15.1) personal area network). In this manner, the computers 704 and the client devices 710 may communicate over various types of transmission mediums.

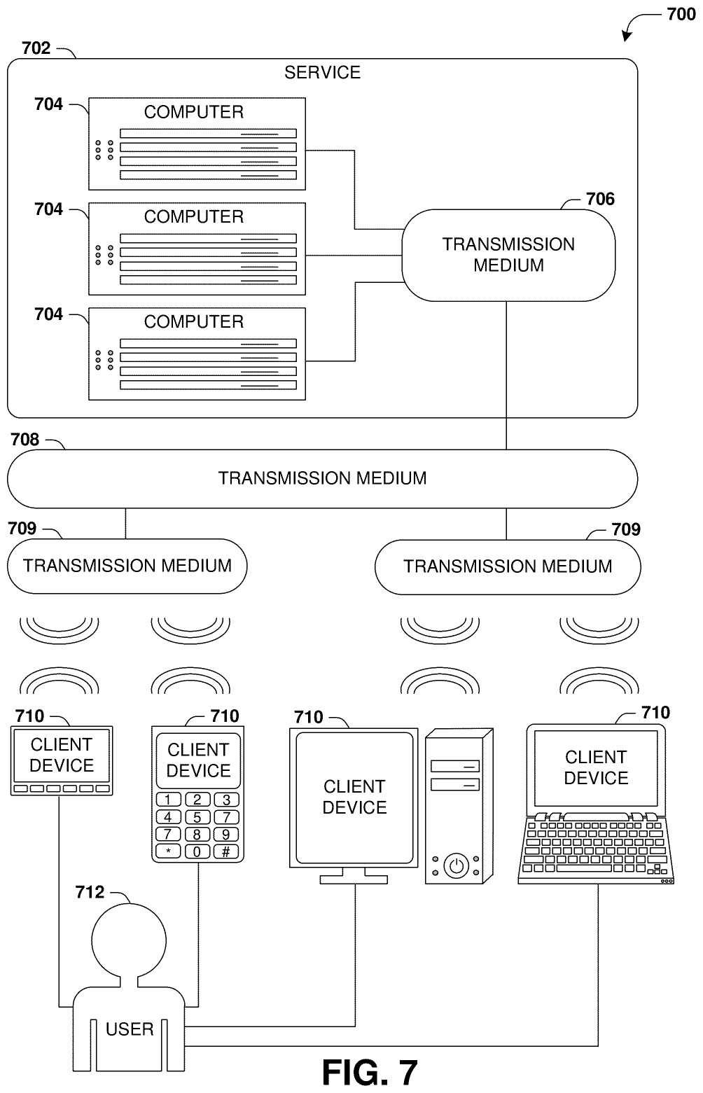

FIG. 8 presents a schematic architecture diagram 800 of a computer 804 that may utilize at least a portion of the techniques provided herein. Such a computer 804 may vary widely in configuration or capabilities, alone or in conjunction with other computers, in order to provide a service.

The computer 804 may comprise one or more processors 810 that process instructions. The one or more processors 810 may optionally include a plurality of cores; one or more coprocessors, such as a mathematics coprocessor or an integrated graphical processing unit (GPU); and/or one or more layers of local cache memory. The computer 804 may comprise memory 802 storing various forms of applications, such as an operating system 804; one or more computer applications 806; and/or various forms of data, such as a database 808 or a file system. The computer 804 may comprise a variety of peripheral components, such as a wired and/or wireless network adapter 814 connectible to a local area network and/or wide area network; one or more storage components 816, such as a hard disk drive, a solid-state storage device (SSD), a flash memory device, and/or a magnetic and/or optical disk reader.

The computer 804 may comprise a mainboard featuring one or more communication buses 812 that interconnect the processor 810, the memory 802, and various peripherals, using a variety of bus technologies, such as a variant of a serial or parallel AT Attachment (ATA) bus protocol; a Uniform Serial Bus (USB) protocol; and/or Small Computer System Interface (SCI) bus protocol. In a multibus scenario, a communication bus 812 may interconnect the computer 804 with at least one other computer. Other components that may optionally be included with the computer 804 (though not shown in the schematic architecture diagram 800 of FIG. 8) include a display; a display adapter, such as a graphical processing unit (GPU); input peripherals, such as a keyboard and/or mouse; and a flash memory device that may store a basic input/output system (BIOS) routine that facilitates booting the computer 804 to a state of readiness.

The computer 804 may operate in various physical enclosures, such as a desktop or tower, and/or may be integrated with a display as an “all-in-one” device. The computer 804 may be mounted horizontally and/or in a cabinet or rack, and/or may simply comprise an interconnected set of components. The computer 804 may comprise a dedicated and/or shared power supply 818 that supplies and/or regulates power for the other components. The computer 804 may provide power to and/or receive power from another computer and/or other devices. The computer 804 may comprise a shared and/or dedicated climate control unit 820 that regulates climate properties, such as temperature, humidity, and/or airflow. Many such computers 804 may be configured and/or adapted to utilize at least a portion of the techniques presented herein.

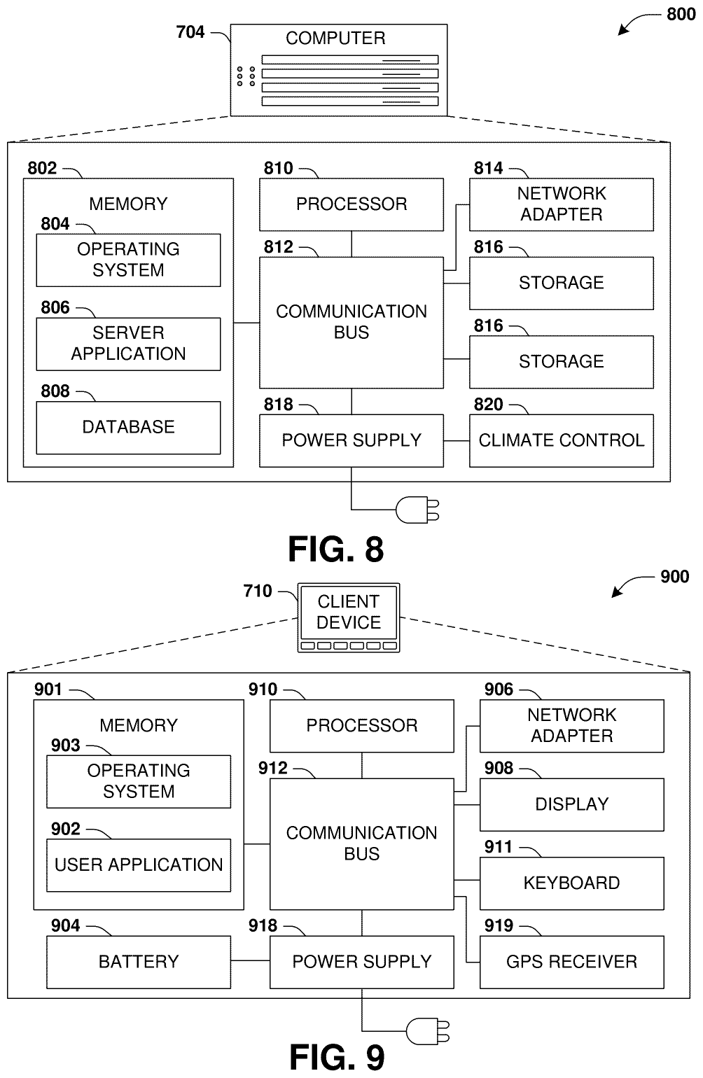

FIG. 9 presents a schematic architecture diagram 900 of a client device 710 whereupon at least a portion of the techniques presented herein may be implemented. Such a client device 710 may vary widely in configuration or capabilities, in order to provide a variety of functionality to a user such as the user 712. The client device 710 may be provided in a variety of form factors, such as a desktop or tower workstation; an “all-in-one” device integrated with a display 908; a laptop, tablet, convertible tablet, or palmtop device; a wearable device mountable in a headset, eyeglass, earpiece, and/or wristwatch, and/or integrated with an article of clothing; and/or a component of a piece of furniture, such as a tabletop, and/or of another device, such as a vehicle or residence. The client device 710 may serve the user in a variety of roles, such as a workstation, kiosk, media player, gaming device, and/or appliance.

The client device 710 may comprise one or more processors 910 that process instructions. The one or more processors 910 may optionally include a plurality of cores; one or more coprocessors, such as a mathematics coprocessor or an integrated graphical processing unit (GPU); and/or one or more layers of local cache memory. The client device 710 may comprise memory 901 storing various forms of applications, such as an operating system 903; one or more user applications 902, such as document applications, media applications, file and/or data access applications, communication applications such as web browsers and/or email clients, utilities, and/or games; and/or drivers for various peripherals. The client device 710 may comprise a variety of peripheral components, such as a wired and/or wireless network adapter 906 connectible to a local area network and/or wide area network; one or more output components, such as a display 908 coupled with a display adapter (optionally including a graphical processing unit (GPU)), a sound adapter coupled with a speaker, and/or a printer; input devices for receiving input from the user, such as a keyboard 911, a mouse, a microphone, a camera, and/or a touch-sensitive component of the display 908; and/or environmental sensors, such as a global positioning system (GPS) receiver 919 that detects the location, velocity, and/or acceleration of the client device 710, a compass, accelerometer, and/or gyroscope that detects a physical orientation of the client device 710. Other components that may optionally be included with the client device 710 (though not shown in the schematic architecture diagram 900 of FIG. 9) include one or more storage components, such as a hard disk drive, a solid-state storage device (SSD), a flash memory device, and/or a magnetic and/or optical disk reader; and/or a flash memory device that may store a basic input/output system (BIOS) routine that facilitates booting the client device 710 to a state of readiness; and a climate control unit that regulates climate properties, such as temperature, humidity, and airflow.

The client device 710 may comprise a mainboard featuring one or more communication buses 912 that interconnect the processor 910, the memory 901, and various peripherals, using a variety of bus technologies, such as a variant of a serial or parallel AT Attachment (ATA) bus protocol; the Uniform Serial Bus (USB) protocol; and/or the Small Computer System Interface (SCI) bus protocol. The client device 710 may comprise a dedicated and/or shared power supply 918 that supplies and/or regulates power for other components, and/or a battery 904 that stores power for use while the client device 710 is not connected to a power source via the power supply 918. The client device 710 may provide power to and/or receive power from other client devices.

As used in this application, “component,” “module,” “system”, “interface”, and/or the like are generally intended to refer to a computer-related entity, either hardware, a combination of hardware and software, software, or software in execution. For example, a component may be, but is not limited to being, a process running on a processor, a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers.

Unless specified otherwise, “first,” “second,” and/or the like are not intended to imply a temporal aspect, a spatial aspect, an ordering, etc. Rather, such terms are merely used as identifiers, names, etc. for features, elements, items, etc. For example, a first object and a second object generally correspond to object A and object B or two different or two identical objects or the same object.

Moreover, “example” is used herein to mean serving as an example, instance, illustration, etc., and not necessarily as advantageous. As used herein, “or” is intended to mean an inclusive “or” rather than an exclusive “or”. In addition, “a” and “an” as used in this application are generally construed to mean “one or more” unless specified otherwise or clear from context to be directed to a singular form. Also, at least one of A and B and/or the like generally means A or B or both A and B. Furthermore, to the extent that “includes”, “having”, “has”, “with”, and/or variants thereof are used in either the detailed description or the claims, such terms are intended to be inclusive in a manner similar to the term “comprising”.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. Of course, many modifications may be made to this configuration without departing from the scope or spirit of the claimed subject matter.

Various operations of embodiments are provided herein. In an embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering may be implemented without departing from the scope of the disclosure. Further, it will be understood that not all operations are necessarily present in each embodiment provided herein. Also, it will be understood that not all operations are necessary in some embodiments.

Also, although the disclosure has been shown and described with respect to one or more implementations, alterations and modifications may be made thereto and additional embodiments may be implemented based upon a reading and understanding of this specification and the annexed drawings. The disclosure includes all such modifications, alterations and additional embodiments and is limited only by the scope of the following claims. The specification and drawings are accordingly to be regarded in an illustrative rather than restrictive sense. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

In the preceding specification, various example embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense. To the extent the aforementioned implementations collect, store, or employ personal information of individuals, groups or other entities, it should be understood that such information shall be used in accordance with all applicable laws concerning protection of personal information. Additionally, the collection, storage, and use of such information can be subject to consent of the individual to such activity, for example, through well known “opt-in” or “opt-out” processes as can be appropriate for the situation and type of information. Storage and use of personal information can be in an appropriately secure manner reflective of the type of information, for example, through various access control, encryption and anonymization techniques for particularly sensitive information.

What is claimed:

1. A method, comprising:
converting input data values into grouping structures;
deriving and assigning categories to the grouping structures based upon types of input data values grouped into the grouping structures;
removing categorical values and time series values from the grouping structures;
training a model to compress the input data values by representing groupings of the input data values using hash values generated from the grouping structures; and
storing the categories and hash values as compressed data representing the input data values.

2. The method of claim 1, comprising:
compressing, by the model, data values by predicting hash values to store in place of the data values based upon the categories.

3. The method of claim 2, comprising:
generating feedback data based upon the predicted hash values; and
training the model using the feedback data.

4. The method of claim 1, comprising:
receiving user input identifying at least one of a missing data value from the compressed data, an unknown data value within the compressed data, an inconsistency category, or a timestamp issue; and
training the model based upon the user input.

5. The method of claim 1, comprising:
evaluating the input data values to identify a set of input data values associated with a category;
grouping the set of input data values into a grouping structure; and
compressing one or more input data values within the grouping structure by representing the one or more input data values with a hash value, wherein the one or more input data values are representative of a same value.

6. The method of claim 1, comprising:
evaluating the input data values to identify a set of input data values associated with a category;
grouping the set of input data values into a grouping structure; and
compressing one or more input data values within the grouping structure by representing the one or more input data values with a hash value, wherein the one or more input data values are representative of an aggregated set of values.

7. The method of claim 6, wherein the grouping structure comprises a tensor, wherein the input data values comprise key performance indicator data, and wherein the model is a large language model.

8. The method of claim 1, comprising:
receiving a request for one or more input data values;
retrieving a hash value representing the one or more input data values; and
reconstructing the one or more input data values from the hash value.

9. A system, comprising:
one or more processors configured for executing instructions to perform operations comprising:
converting input data values into grouping structures;
deriving and assigning categories to the grouping structures based upon types of input data values grouped into the grouping structures;
removing categorical values and time series values from the grouping structures;
training a model to compress the input data values by representing groupings of the input data values using hash values generated from the grouping structures; and
storing the categories and hash values as compressed data representing the input data values.

10. The system of claim 9, wherein the operations further comprise:
training the model using a training data set including classifiers for different types of input data values.

11. The system of claim 9, wherein the operations further comprise:
training the model using a training data set including user specified classifiers for different types of data values.

12. The system of claim 9, wherein the operations further comprise:
training the model using a training data set including training data values and hints for how to group the training data values.

13. The system of claim 9, wherein the operations further comprise:
providing a user with an artificial intelligence interface;
receiving text from the user through the artificial intelligence interface, wherein the text describes a grouping for data values; and
training the model based upon the text.

14. The system of claim 9, wherein the operations further comprise:
providing a user with an artificial intelligence interface;
receiving text from the user through the artificial intelligence interface, wherein the text describes at least one of summations, groupings, counts, or columns to combine as part of compression provided by the model; and
training the model based upon the text.

15. The system of claim 9, wherein the operations further comprise:
generating, by the model, a new grouping structure based upon a category determined by the model; and
training the model based upon the data values grouped into the new grouping structure and a hash value assigned to the new grouping structure.

16. The system of claim 9, wherein the operations further comprise:
training the model with patterns corresponding to grouped columns within which the input data values are stored.

17. A non-transitory computer-readable medium storing instructions that when executed facilitate performance of operations comprising:
converting input data values into grouping structures;
deriving and assigning categories to the grouping structures based upon types of input data values grouped into the grouping structures;
removing categorical values and time series values from the grouping structures;
training a model to compress the input data values by representing groupings of the input data values using hash values generated from the grouping structures; and
storing the categories and hash values as compressed data representing the input data values.

18. The non-transitory computer-readable medium of claim 15, wherein the operations further comprise:
transforming the input data values into image data representations;
grouping the image data representations into the grouping structures; and
compressing the image data representations by storing a single value per category.

19. The non-transitory computer-readable medium of claim 15, wherein the operations further comprise:
evaluating previously learned dataset and schemas to identify patterns for compression, wherein the patterns correspond to grouped columns within which the input data values are stored; and
training the model with the patterns.

20. The non-transitory computer-readable medium of claim 15, wherein the operations further comprise:
receiving a request for data values associated with a category; and
rebuilding the data values from hash values assigned to the category.
